(19) United States
(12) Patent Application Publication
(10) Pub. No.: US 2026/0209938 A1
(43) Pub. Date: Jul. 23, 2026

(54) METHOD OF MANUFACTURING AN ULTRA-THIN INSULATING LAYER HAVING REDUCED LEAKAGE CURRENT DENSITY

(71) Applicant: MIIN-JANG CHEN, Taipei City (TW)

(72) Inventor: MIIN-JANG CHEN, Taipei City (TW)

(21) Appl. No.: 19/406,225

(22) Filed: Dec. 2, 2025

Related U.S. Application Data
(60) Provisional application No. 63/726,843, filed on Dec. 2, 2024.

(51) Int. Cl. C23C 16/455; C23C 16/34; C23C 16/40; C23C 16/44; C23C 16/56; H10P 14/60; H10P 14/692

(52) U.S. Cl. CPC C23C 16/4554; C23C 16/34; C23C 16/405; C23C 16/4408; C23C 16/56; H10P 14/6339; H10P 14/69392; H10P 14/69395; H10P 14/69397

(57) ABSTRACT

A method of manufacturing an ultra-thin insulating layer with reduced leakage current density is performed by a plurality of atomic layer deposition (ALD) cycles. In each ALD cycle, an in-situ hydrogen plasma treatment step is introduced at a predetermined time point. The hydrogen plasma treatment step is performed either after the precursor has been adsorbed on a material layer of a material structure and before the reactant is introduced into the reaction chamber, or after the reactant has been introduced.

### CROSS-REFERENCE TO RELATED APPLICATION

This utility application claims priority to U.S. Provisional Application Ser. No. 63/726,843, filed Dec. 2, 2024, which is incorporated herein by reference.

### BACKGROUND OF THE INVENTION

### 1. Field of the Invention

The invention relates to a method of manufacturing an ultra-thin insulating layer, and more in particular, to a method of manufacturing an ultra-thin insulating layer having excellent film quality and extremely low leakage current density by an improved atomic layer deposition (ALD) process. The ultra-thin insulating layer manufactured according to the method of the present invention may be formed of metal oxides, metalloid oxides, metal nitrides or metalloid nitrides, and may be applied to dielectric layers of semiconductor devices, or surface passivation layers of systems that generate thermal energy, such as integrated circuits, optoelectronic devices, and micro-electromechanical systems.

### 2. Description of the Prior Art

Metal oxides or metalloid oxides (e.g., silicon dioxide (SiO₂)) and metal nitrides or metalloid nitrides (e.g., silicon nitride (SiNₓ)) are widely used for dielectric layers in semiconductor devices and surface passivation layers in systems that generate thermal energy, such as integrated circuits, optoelectronic devices, and micro-electromechanical systems. With the rapid progress of these high-performance devices, their operating power has also increased. Therefore, in the field of thermal management of these systems, there is an urgent need for high-performance insulating layers.

When heat flows cross an interface between different materials, the interfacial thermal resistance (Rᵢₙₜ) produces a barrier that hinders heat transmission. The greater the Rᵢₙₜ, the more impeded the heat transfer across the interface becomes, which leads to a reduction in overall thermal conductance. For nano-scale insulating thin films, interfacial thermal resistance (Rᵢₙₜ) is a dominant factor influencing heat transfer characteristics. The total thermal conductance (Gₜₒₜₐₗ) and total thermal resistance (Rₜₒₜₐₗ) of a thin film are influenced by both the intrinsic thermal conductivity (k) of the material and the interfacial thermal resistance (Rᵢₙₜ), wherein the combination thereof determines the final heat transmission behavior:

$${R}_{total} = \frac{1}{{G}_{total}} = {R}_{int 1} + {R}_{film} + {R}_{int 2} = {R}_{int 1} + \frac{d}{k \cdot A} + {R}_{int 2} \qquad Equation ( 1 )$$

Wherein A is the cross-sectional area, Rᵢₙₜ₁ and Rᵢₙₜ₂ are the interfacial thermal resistances of interfaces 1 and 2, respectively, and R_{film} is the thermal resistance of the thin film itself. Based on the above analysis, it is evident that as the film thickness d decreases, the contribution of the interfacial thermal resistance (Rᵢₙₜ₁, Rᵢₙₜ₂) to the total thermal resistance (Rₜₒₜₐₗ) increases. Under these conditions, the total thermal resistance (Rₜₒₜₐₗ) is primarily dominated by the interfacial thermal resistances. Consequently, reducing the film thickness can effectively enhance the overall thermal conductance. In previous studies, the inventors of the present invention compared an AlN thin film fabricated by an atomic layer deposition (ALD) process (ALD AlN film) with an AlN thin film fabricated by an atomic layer annealing (ALA) process (ALA AlN film). The ALA process involves an in-situ He/Ar plasma treatment after each ALD cycle to anneal the atomic-level AlN. The results showed that the crystalline quality of the ALA AlN film was superior to that of the ALD AlN film. Thermal conductance studies of these two AlN films confirmed that in cases where the film thickness is extremely thin (less than 10 nanometers), the overall thermal conductance is primarily determined by the interfacial thermal conductance, while the crystalline structure of the film itself has a relatively minor impact. Therefore, reducing the thickness of the insulating layer as much as possible, without sacrificing electrical insulation, is an effective way to improve overall heat dissipation efficiency.

In addition, driven by the continuous evolution of Moore's law, the dimensions of semiconductor devices continue to shrink, and the degree of integration steadily increases. To maintain effective control over the transistor channel at reduced dimensions and suppress short channel effects, the thickness of the gate dielectric layer must be scaled down accordingly. However, when the physical thickness of conventional silicon dioxide (SiO₂) based gate dielectric layers is reduced to below several nanometers. This leads to a sharp increase in device power consumption and a degradation in performance, resulting a physical bottleneck for device miniaturization.

To address this challenge, materials with a high dielectric constant (high-k), such as hafnium oxide (HfO₂), zirconium oxide (ZrO₂), etc., have been widely studied and used to replace conventional silicon dioxide. These materials allow for a larger physical thickness at the same capacitance equivalent thickness (CET), thereby suppressing leakage current. Atomic layer deposition (ALD) technology, due to its unique self-limiting surface chemical reaction mechanism, is capable of precisely controlling the thickness, composition, and uniformity of thin films at the atomic scale. Furthermore, ALD possesses excellent three-dimensional conformal coverage capability (conformality), making it a widely adopted technology for depositing high-quality nano-scale high-k dielectric layers.

Furthermore, taking integrated circuits as an example, a typical surface passivation layer comprises a SiO₂/Si₃N₄ bilayer structure. The first layer, disposed on the top metal layer, is SiO₂ formed by a plasma enhanced chemical vapor deposition (PECVD) process. It typically has a thickness of about hundreds of nanometers to 1 micrometer, serving to provide good dielectric isolation. The second layer, which serves as the outermost layer, is Si₃N₄ formed by a PECVD process. It also typically has a thickness of about hundreds of nanometers to 1 micrometer, acting as a protective layer to prevent moisture and impurities such as sodium ions from penetrating the chip interior. Consequently, such a typical surface passivation layer exhibits high thermal resistance, unless its thickness is significantly reduced.

However, whether used as a gate dielectric layer for semiconductor devices, or as a surface passivation layer for systems that generate thermal energy such as integrated circuits, optoelectronic devices, micro-electromechanical systems, etc., when the physical thickness of the insulating layer is reduced to the nanometer level, severe challenges associated with significantly increased leakage current density arise. Conventional ALD processes, however, have several limitations. For example, after the organometallic precursor used in the process chemisorbs on the surface, its residual organic ligands often cause steric hindrance. This blocks the reaction sites for subsequent reactants, leading to incomplete chemical reactions and introducing defects, such as oxygen vacancies and carbon residues, into the thin film. These defects act as primary paths for leakage current. Furthermore, although a lower ALD process temperature (usually lower than 300° C.) is beneficial for staying within the thermal budget, it limits the surface mobility of adatoms of adatoms during the film deposition process, resulting in insufficient film density.

In summary, there is a need to improve conventional ALD processes to enhance the internal structure and material quality of the ultra-thin insulating layer. Such improvements are necessary to effectively suppress leakage current, thereby meeting the requirements of next-generation semiconductor devices. Furthermore, these improvements would enable a reduction in the thickness of the insulating layer, thereby enhancing overall heat dissipation efficiency of the ultra-thin insulating layer.

### SUMMARY OF THE INVENTION

An objective of the present invention is to solve the problems associated with the prior art described above and to provide a method for reducing the leakage current density of an ultra-thin insulating layer. The method according to the present invention can precisely regulate the growth mechanism of the thin film in a layer-by-layer and in-situ manner during the atomic layer deposition process, thereby significantly improving film quality and effectively suppressing leakage current.

Another object of the present invention is to provide a process framework with high flexibility and universality. The method according to the present invention can be applied to various insulating materials such as metal oxides, metalloid oxides, metal nitrides or metalloid nitrides. Furthermore, various electrical characteristics, including leakage current density, interface quality, reliability, and frequency dispersion, can be optimized by adjusting process parameters.

According to a preferred embodiment of the present invention, a method of manufacturing an ultra-thin insulating layer on a material layer of a material structure is performed by a plurality of atomic layer deposition (ALD) cycles. The material structure is placed in a reaction chamber. Each ALD cycle includes the following steps: (a) introducing at least one first gas pulse into the reaction chamber, the at least one first gas pulse including at least one precursor, to cause the precursor to be adsorbed on the material layer of the material structure, wherein the precursor includes a metal element or a metalloid element; (b) introducing a purge gas into the reaction chamber; (c) introducing a second gas pulse into the reaction chamber to react with the precursor adsorbed on the material layer to form an atomic layer of the ultra-thin insulating layer, wherein the second gas pulse includes a reactant; (d) introducing the purge gas into the reaction chamber again; and (e) alternatively, between step (b) and step (c) or after step (d), introducing a hydrogen plasma into the reaction chamber and subsequently introducing the purge gas into the reaction chamber.

In one embodiment, a plasma power of the hydrogen plasma ranges from 10 W to 600 W.

In one embodiment, a duration of introducing the hydrogen plasma step ranges from 3 seconds to 60 seconds.

Furthermore, the method according to the present invention involves performing a post-metallization annealing (PMA) treatment on the ultra-thin insulating layer in a mixed gas atmosphere of 5% H₂/95% N₂. The post-metallization annealing treatment is performed at a temperature ranging from 300° C. to 1000° C., and for a duration ranging from 3 seconds to 10 minutes.

In one embodiment, the ultra-thin insulating layer manufactured by the method according to the present invention is formed of a metal oxide or a metalloid oxide. The metal oxide or the metalloid oxide material may be selected from the group consisting of HfO₂, ZrO₂, HfₓZr₁₋ₓO₂ (0≤x≤1), Ta₂O₃, Al₂O₃, Gd₂O₃, La₂O₃, SiO₂, TiO₂, Y₂O₃, other metal oxides, other metalloid oxides, and combinations thereof.

In another embodiment, the ultra-thin insulating layer manufactured by the method according to the present invention is formed of a metal nitride or a metalloid nitride. The metal nitride or the metalloid nitride may be selected from the group consisting of AlNₓ, SiNₓ, GeNₓ, BNₓ, other metal nitrides, other metalloid nitrides, and combinations thereof, wherein 0.5≤x≤1.5.

In one embodiment, the ultra-thin insulating layer manufactured by the method according to the present invention serves as a dielectric layer, and a leakage current density of the ultra-thin insulating layer is equal to or less than 2×10⁻⁵ A/cm².

In one embodiment, the ultra-thin insulating layer manufactured by the method according to the present invention serves as a surface passivation layer, and a leakage current density of the ultra-thin insulating layer is equal to or less than 1×10⁻⁶ A/cm².

In one embodiment, the material structure may be an integrated circuit component structure, an optoelectronic component structure, a micro-electromechanical component structure, or other component structures that generate thermal energy. The ultra-thin insulating layer manufactured by the method according to the present invention can serve as a surface passivation layer. A thickness range of the ultra-thin insulating layer as the surface passivation layer may be from 3 nm to 50 nm.

In contrast to the prior art, the method according to embodiments of the present invention can precisely regulate the growth mechanism of the thin film in a layer-by-layer and in-situ manner during the atomic layer deposition process, thereby significantly improving film quality and substantially suppressing leakage current. Furthermore, the thickness of the ultra-thin insulating layer manufactured according to the method of the present invention can be significantly reduced, thereby effectively enhancing the overall heat dissipation efficiency of the ultra-thin insulating layer.

The advantage and spirit of the present invention may be understood by the following recitations together with the appended drawings.

### BRIEF DESCRIPTION OF THE APPENDED DRAWINGS

FIG. 1 is a flowchart illustrating an ALD cycle included in a plurality of ALD cycles utilized in a method according to a preferred embodiment of the present invention.

FIG. 2 is a flowchart illustrating an ALD cycle included in a plurality of ALD cycles utilized in a method according to another preferred embodiment of the present invention.

FIG. 3 shows the results of dielectric constants measured for various Hf_{0.5}Zr_{0.5}O₂ (HZO) thin film samples fabricated with ALD cycles including hydrogen plasma treatments with different plasma powers, which is the first example of the present invention.

FIG. 4 shows the results of dielectric constants measured for various HZO thin film samples fabricated with ALD cycles including hydrogen plasma treatments with different plasma durations, which is the first example of the present invention.

FIG. 5(a), FIG. 5(b), and FIG. 5(c) are cross-sectional high-resolution transmission electron microscopy (HRTEM) images of metal-oxide-semiconductor (MOS) structures of the first reference example, the second example of the present invention, and the third example of the present invention, respectively.

FIG. 6 is a graph showing capacitance-voltage (C-V) measurement results of the MOS capacitor devices of the first reference example, the second example of the present invention, and the third example of the present invention.

FIG. 7 is a graph showing leakage current density-voltage measurement results of the MOS capacitor devices of the first reference example, the second example of the present invention, and the third example of the present invention.

FIG. 8(a), FIG. 8(b), and FIG. 8(c) show X-ray reflectivity (XRR) patterns and their fitting curves for the HfO₂ ultra-thin insulating layers of the first reference example, the second example of the present invention, and the third example of the present invention, respectively.

FIG. 9 is a graph showing the relationship between normalized parallel conductance (Gₚ/ω) and angular frequency ω measured by the conductance method for the devices of the second example of the present invention, the third example of the present invention, and the first reference example.

FIG. 10(a), FIG. 10(b), and FIG. 10(c) show C-V curves measured at different frequencies for the devices of the second example of the present invention, the third example of the present invention, and the first reference example, respectively.

FIG. 11(a) and FIG. 11(b) show Weibull plots obtained from time-dependent dielectric breakdown (TDDB) lifetime tests performed under different electric fields for the devices of the first reference example and the third example of the present invention, respectively.

FIG. 12 is a graph showing the relationship between characteristic breakdown time and electric field stress for the MOS capacitor devices of the first reference example, the second example of the present invention, and the third example of the present invention.

FIG. 13 is a graph showing capacitance-voltage (C-V) measurement results for devices of a second reference example (reference-4) and HAP (HAP-4).

FIG. 14 is a graph showing leakage current density-voltage measurement results for devices of the second reference example (reference-4) and HAP (HAP-4).

FIG. 15 is a graph showing capacitance-voltage (C-V) measurement results for metal-insulator-metal (MIM) capacitor devices of the third reference example, the fourth example of the present invention, and the fifth example of the present invention.

FIG. 16 is a graph showing leakage current density-voltage measurement results for MIM capacitor devices of the third reference example, the fourth example of the present invention, and the fifth example of the present invention.

### DETAILED DESCRIPTION OF THE INVENTION

Some preferred embodiments and practical applications of this present invention would be explained in the following paragraph, describing the characteristics, spirit, and advantages of the invention.

According to a preferred embodiment of the present invention, a method of manufacturing an ultra-thin insulating layer on a material layer of a material structure is performed by a plurality of atomic layer deposition cycles (ALD cycles). It should be emphasized that the material structure employed in the method according to the preferred embodiment of the present invention may be a finished product or a semi-finished product of components in various fields such as semiconductors, integrated circuits, optoelectronics, and micro-electromechanical systems.

It should be explained first that each ALD cycle is composed of two half cycles. According to the method of the present invention, the ultra-thin insulating layer is formed based on an atomic layer deposition process, and basically, each ALD cycle thereof is also composed of two half cycles. The first half cycle involves introducing a first gas pulse containing a precursor of a predetermined metal or metalloid element into the reaction chamber, followed by introducing a purge gas. The second half cycle involves introducing a second gas pulse containing a reactant into the reaction chamber, followed by introducing a purge gas.

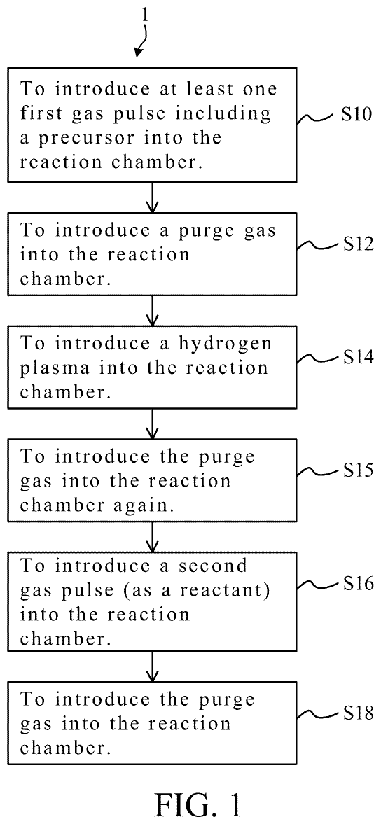

Referring to FIG. 1, FIG. 1 is a flowchart of each ALD cycle 1 included in a plurality of ALD cycles 1 utilized in a method according to the preferred embodiment of the present invention.

As shown in FIG. 1, each ALD cycle 1 first performs step S10 to introduce at least one first gas pulse into the reaction chamber. The at least one first gas pulse includes a precursor to be adsorbed on a material layer of a material structure. The material structure is placed in the reaction chamber in advance. The precursor contains a predetermined metal or metalloid element.

Next, each ALD cycle 1 performs step S12 to introduce a purge gas into the reaction chamber. In one embodiment, the purge gas may be an inert gas (e.g., argon, helium) or a non-reactive gas (e.g., nitrogen). In practical application, the purge gas may also serve as a carrier gas for the precursor.

Then, each ALD cycle 1 performs step S14 to introduce a hydrogen plasma into the reaction chamber. In this step, the highly active hydrogen plasma can react with the organic ligands of the precursor molecules chemically adsorbed on the surface, thereby effectively removing them. This action can significantly reduce steric hindrance caused by ligands and expose more active reaction sites, allowing the subsequent reactant pulse to undergo a more thorough and uniform surface chemical reaction. As a result, the deposited film exhibits a lower defect density, fewer carbon impurity residues, and higher film density, thereby significantly reducing leakage current.

Afterward, each ALD cycle 1 performs step S15 to introduce the purge gas into the reaction chamber again. Subsequently, each ALD cycle 1 performs step S16 to introduce a second gas pulse (as a reactant) into the reaction chamber to react with the precursor already adsorbed on the material layer to form an atomic layer of the ultra-thin insulating layer, wherein the second gas pulse includes the reactant.

Finally, each ALD cycle 1 performs step S18 to introduce the purge gas into the reaction chamber. In the present invention, the operation of introducing hydrogen plasma after the step of introducing the first gas pulse (precursor) is referred to as the HAP (hydrogen after precursor) process.

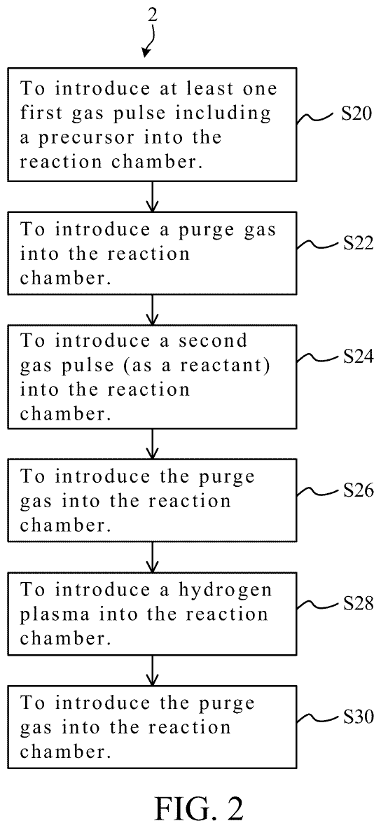

Referring to FIG. 2, FIG. 2 is a flowchart of each ALD cycle 2 included in a plurality of ALD cycles 2 utilized in a method according to another preferred embodiment of the present invention.

As shown in FIG. 2, each ALD cycle 2 first performs step S20 to introduce at least one first gas pulse into the reaction chamber. The at least one first gas pulse includes a precursor to be adsorbed on a material layer of a material structure. The material structure is placed in the reaction chamber in advance. The precursor contains a predetermined metal or metalloid element.

Next, each ALD cycle 2 performs step S22 to introduce a purge gas into the reaction chamber. In one embodiment, the purge gas may be an inert gas (e.g., argon, helium) or a non-reactive gas (e.g., nitrogen). In practical application, the purge gas may also serve as a carrier gas for the precursor.

Then, each ALD cycle 2 performs step S24 to introduce a second gas pulse (as a reactant) into the reaction chamber to react with the precursor already adsorbed on the material layer to form an atomic layer of the ultra-thin insulating layer at an atomic level, wherein the second gas pulse includes the reactant.

Afterward, each ALD cycle 2 performs step S26 to introduce the purge gas into the reaction chamber.

Subsequently, each ALD cycle 2 performs step S28 to introduce a hydrogen plasma into the reaction chamber. In this step, the energy provided by the hydrogen plasma is transferred to the newly formed atomic layer of the ultra-thin insulating layer. This process facilitates the migration and rearrangement of adatoms to achieve an atomic-level annealing effect, thereby improving the density and structure of the ultra-thin insulating layer.

Finally, each ALD cycle 2 performs step S30 to introduce the purge gas into the reaction chamber. In the present invention, the operation of introducing hydrogen plasma after the step of introducing the second gas pulse (reactant) is referred to as the HAO (hydrogen after oxidant) process.

In one embodiment, each ALD cycle is performed at a specific process temperature and process pressure. The process temperature ranges from 100° C. to 500° C., and the process pressure ranges from 0.1 Pa to 1000 Pa.

Furthermore, the method according to the present invention involves performing a post-metallization annealing (PMA) treatment on the ultra-thin insulating layer in a mixed gas atmosphere of 5% H₂/95% N₂. The temperature range of the post-metallization annealing treatment ranges from 300° C. to 1000° C. The duration of the post-metallization annealing treatment ranges from 3 seconds to 10 minutes. It should be noted that other types of post-annealing treatments may be performed on the ultra-thin insulating layer, wherein the temperature range of the post-annealing treatment ranges from 300° C. to 1000° C., and the duration of the post-annealing treatment ranges from 3 seconds to 10 minutes.

In one embodiment, the ultra-thin insulating layer manufactured by the method according to the present invention is formed of a metal oxide or a metalloid oxide. The metal oxide or the metalloid oxide may be selected from the group consisting of HfO₂, ZrO₂, HfₓZr₁₋ₓO₂ (0≤x≤1), Ta₂O₃, Al₂O₃, Gd₂O₃, La₂O₃, SiO₂, TiO₂, Y₂O₃, other metal oxides, other metalloid oxides, and combinations thereof.

The precursor supplying the hafnium (Hf) element may be selected from the group consisting of HfCl₄, HfI₄, HfCl₂[N(SiMe₃)₂]₂, HfCp₂Me₂, HfCp₂Cl₂, Hf(CpMe)₂Me₂, Hf(CpMe)₂(OMe)Me, Hf(CpMe)₂(OⁱPr)Me, Hf(CpMe)₂(mmp)Me, Hf(Cp)(NMe₂)₃, Hf(CpMe)(NMe₂)₃, Hf(Cp₂CMe₂)Me₂, Hf(Cp₂CMe₂)Me(OMe), Hf(OⁱPr)₄, Hf(O^{t}Bu)₄, Hf(O^{t}Bu)₂(mmp)₂, Hf(O^{t}Bu)(NEtMe)₃, Hf(mmp)₄, Hf(mp)₄, Hf(ONEt₂)₄, Hf(NMe₂)₄, Hf(NEt₂)₄, Hf(NEtMe)₄, Hf[N(SiMe₃)₂]₂Cl₂, Hf(NO₃)₄, and combinations thereof. The reactant supplying the O element may be O₂ plasma, N₂O plasma, O₃, H₂O, H₂O₂, and combinations thereof.

The precursor supplying the zirconium (Zr) element may be selected from the group consisting of ZrCl₄, ZrI₄, ZrCp₂Cl₂, ZrCp₂Me₂, ZrCp₂Me(OMe), ZrCp(NMe₂)₃, Zr(CpMe)₂Me₂, Zr(CpMe)₂Me(OMe), Zr(CpMe)(NMe₂)₃, Zr(CpEt)(NMe₂)₃, Zr(Cp₂CMe₂)Me₂, Zr(Cp₂CMe₂)Me(OMe), Zr(OⁱPr)₄, Zr(OⁱPr)₂(dmae)₂, Zr(O^{t}Bu)₄, Zr(O^{t}Bu)₂(dmae)₂, Zr(dmae)₄, Zr(thd)₄, Zr(NMe₂)₄, Zr(NEt₂)₄, Zr(NEtMe)₄, Zr[N(SiMe₃)₂]₂Cl₂, Zr(MeAMD)₄, and combinations thereof.

The precursor supplying the aluminum (Al) element may be selected from the group consisting of AlCl₃, AlBr₃, Al(CH₃)₃ (trimethylaluminum, TMA), AlMe₂Cl, AlMe₂OⁱPr, AlEt₃, Al(OEt)₃, Al(OnPr)₃, Al(mmp)₃, Al(NEt₂)₃, Al(NiPr₂)₃, Al(ⁱPrAMD)Et₂, and combinations thereof.

The precursor supplying the titanium (Ti) element may be selected from the group consisting of TiF₄, TiCl₄, TiI₄, Ti[N(CH₃)₂]₄ (tetrakis(dimethylamino)titanium, TDMAT), Ti[N(C₂H₅)₂]₄, Ti(CpMe₅)(OMe)₃, Ti(CpMe)(OⁱPr)₃, Ti(OMe)₄, Ti(OEt)₄, Ti(OⁱPr)₄, Ti(OⁱPr)₂(dmae)₂, Ti(OⁱPr)₂(thd)₂, Ti(trhd)₂(O(CMe₂Et)₂, Ti(OBu)₄, Ti(NMe₂)₄, TiCp₂((ⁱPrN)₂C(NHⁱPr)), and combinations thereof.

The precursor supplying the lanthanum (La) element may be selected from the group consisting of La(thd)₃, La[N(SiMe₃)₂]₃, La(ⁱPrAMD)₃, La(ⁱPrfAMD)₃, La(Cp)₃, La(CpEt)₃, La(CpⁱPr)₃, and combinations thereof.

The precursor supplying the silicon (Si) element may be selected from the group consisting of SiCl₄, Si₂Cl₆, SiCl₃H, SiCl₂H₂, SiH₄, Si(OMe)₄, Si(OEt)₄, Si(OEt)₃((CH₂)₃NH₂), Si(OⁱPe)₃OH, HMDS, SiH₂(N(CH₃)₂)₂, SiH₂(NH^{t}Bu)₂, SiH₂(NEt₂)₂, SiH(N(CH₃)₂)₃, Si(NCO)₄, MeOSi(NCO)₃, (SiH₃)₃N (trisilylamine, TSA), and combinations thereof.

The precursor supplying the yttrium (Y) element may be selected from the group consisting of Y(thd)₃, YCp₃, Y(CpMe)₃, Y(CpEt)₃, Y(ⁱPrAMD)₃, and combinations thereof.

In another embodiment, the ultra-thin insulating layer manufactured by the method according to the present invention is formed of a metal nitride or a metalloid nitride. The metal nitride or the metalloid nitride may be selected from the group consisting of AlNₓ, SiNₓ, GeNₓ, BNₓ, other metal nitrides, other metalloid nitride, and combinations thereof, wherein 0.5≤x≤1.5.

The precursors supplying the Hf, Zr, Al, Ti, La, Si, and Y elements are as described above. The precursor supplying the germanium (Ge) element may be Ge(NMe₂)₄ (Me=CH₃, tetrakis(dimethylamino)germane, TDMAGe), etc. The reactant supplying the nitrogen (N) element may be selected from the group consisting of ammonia (NH₃) plasma, a mixed gas of nitrogen and hydrogen (N₂/H₂) plasma, and combinations thereof.

In one embodiment, the ultra-thin insulating layer manufactured by the method according to the present invention serves as a dielectric layer, and the leakage current density of the ultra-thin insulating layer is equal to or less than 2×10⁻⁵ A/cm².

In one embodiment, the ultra-thin insulating layer manufactured by the method according to the present invention serves as a surface passivation layer, and the leakage current density of the ultra-thin insulating layer is equal to or less than 1×10⁻⁶ A/cm².

In one embodiment, the material structure may be an integrated circuit component structure, an optoelectronic component structure, a micro-electromechanical component structure, or other component structures that generate thermal energy. The ultra-thin insulating layer manufactured by the method according to the present invention can serve as a surface passivation layer. A thickness range of the ultra-thin insulating layer as the surface passivation layer may be from 3 nm to 50 nm.

In one embodiment, the plasma power of the hydrogen plasma ranges from 10 W to 600 W.

In one embodiment, the duration of introducing the hydrogen plasma step ranges from 3 seconds to 60 seconds.

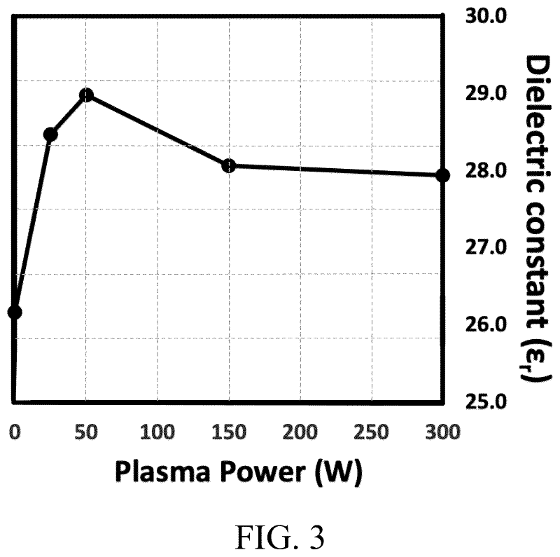

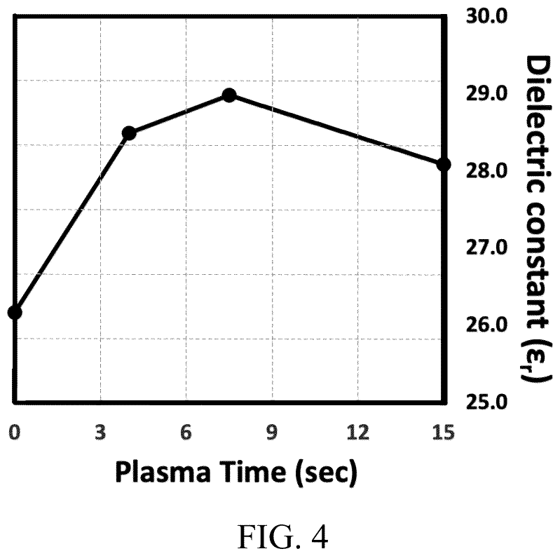

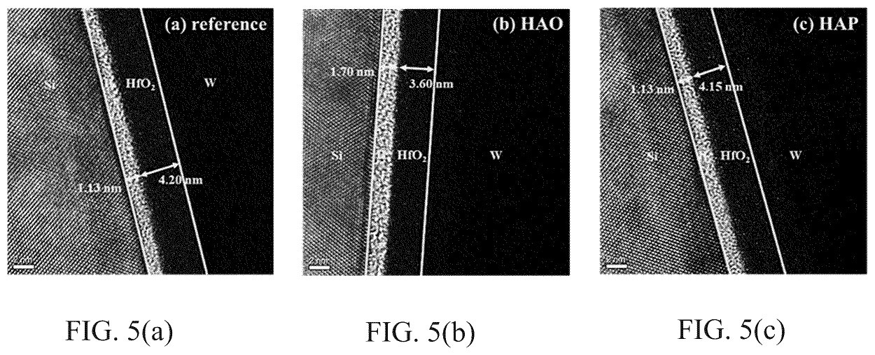

In the first example of the present invention, a Hf_{0.5}Zr_{0.5}O₂ (HZO) thin film was fabricated according to the method of the present invention, utilizing the HAP process depicted in FIG. 1 to form an ultra-thin insulating layer with a thickness of about 7.5 nm. The first example further introduces hydrogen plasma treatments with different plasma powers and different plasma durations to manufacture HZO thin films. Referring to FIG. 3 and FIG. 4, FIG. 3 shows the results of dielectric constants measured for various HZO thin films fabricated with ALD cycles including hydrogen plasma treatments with different plasma powers, which is the first example of the present invention. FIG. 4 shows the results of dielectric constants measured for various HZO thin films fabricated with ALD cycles including hydrogen plasma with different plasma durations, which is the first example of the present invention. The results in FIG. 3 show that the dielectric constant of the HZO film increases to a peak value as the plasma power increases, and then decreases. Similarly, the results in FIG. 4 also show that as the plasma duration increases, the dielectric constant of the HZO film first rises to a peak value and then decreases. The results of FIG. 3 and FIG. 4 indicate that the plasma power of the hydrogen plasma disclosed in the present invention preferably ranges from 25 W to 300 W, and the duration of the hydrogen plasma treatment preferably ranges from 4 seconds to 15 seconds. Extrapolation based on the results of FIG. 3 and FIG. 4 supports the declared plasma power range of hydrogen plasma in the present invention being from 10 W to 600 W, and the duration range of the hydrogen plasma treatment being from 3 seconds to 60 seconds. The results of FIG. 3 and FIG. 4 further indicate that the plasma power of 50 W and the plasma duration of 7.5 seconds represent the optimal condition for hydrogen plasma treatment, maximizing the dielectric constant of the HZO thin film.

In the second example, the third example, and the first reference example of the present invention, hafnium oxide (HfO₂) high-k dielectric layers were fabricated to form metal-oxide-semiconductor (MOS) capacitor devices. The MOS capacitor devices were fabricated on a p-type (100) silicon substrate with a resistivity of 1-10 Ω·cm. The structure, from bottom to top, comprises an aluminum (Al) back electrode, a p-Si substrate, the hafnium oxide (HfO₂) high-k dielectric layer, and a tungsten (W) top electrode. The precursor used in the second example, the third example, and the first reference example of the present invention was tetrakis(dimethylamino) hafnium (TDMAHf), and the reactant was water vapor (H₂O). The deposition temperature of the HfO₂ ultra-thin insulating layer was set to 300° C.

The second example of the present invention utilizes the HAO process described in the present invention, wherein the energy provided by the hydrogen plasma can be transferred to the newly formed atomic layer of the HfO₂ film. This process facilitates the migration and rearrangement of adatoms to achieve an atomic-level annealing effect, thereby improving the density and structure of the HfO₂ film. The second example of the present invention employed a hydrogen plasma treatment with a plasma power of 50 W and a plasma duration of 7.5 seconds.

The third example of the present invention utilizes the HAP process described in the present invention. The key mechanism of this process is that prior to introducing the H₂O reactant, a hydrogen plasma treatment is introduced to effectively remove the organic ligands on the TDMAHf molecules chemically adsorbed on the surface. Removing these ligands can significantly reduce steric hindrance, allowing subsequent H₂O molecules to undergo a more complete chemical reaction with Hf atoms, thereby forming a HfO₂ film with reduced defect density and enhanced quality.

The MOS capacitor devices containing the HfO₂ ultra-thin insulating layer fabricated in the second example, the third example, and the first reference example of the present invention were all subjected to rapid thermal annealing at 450° C. for 5 minutes in an atmosphere containing 5% H₂/95% N₂ mixed gas (forming gas) to complete post-metallization annealing (PMA). In the figures described below, the symbol “reference” denotes the device of the first reference example, the symbol “HAO” denotes the device of the second example, and the symbol “HAP” denotes the device of the third example.

FIG. 5(a), FIG. 5(b), and FIG. 5(c) are cross-sectional HRTEM images of MOS capacitor devices of the first reference example, the second example, and the third example, respectively. As observed in FIG. 5(a), FIG. 5(b), and FIG. 5(c), the total physical thickness of the HfO₂ dielectric layer and interfacial layer (IL) for all three devices is about 5.3 nm. This result is consistent with the measurement results obtained via spectroscopic ellipsometry. It is worth noting that the IL thickness of the second example sample is the thickest (about 1.70 nm), while the IL thicknesses of the third example and the first reference example samples are thinner (both about 1.13 nm). The thicker IL of the second example sample is attributed to the hydrogen plasma treatment being applied after the reactant pulse. In this process, plasma energy acts directly on the surface where Hf—O bonds are formed, promoting the diffusion of oxygen atoms to the HfO₂/Si interface, thereby leading to an increased thickness of the silicon oxide (SiOₓ) layer at the interface.

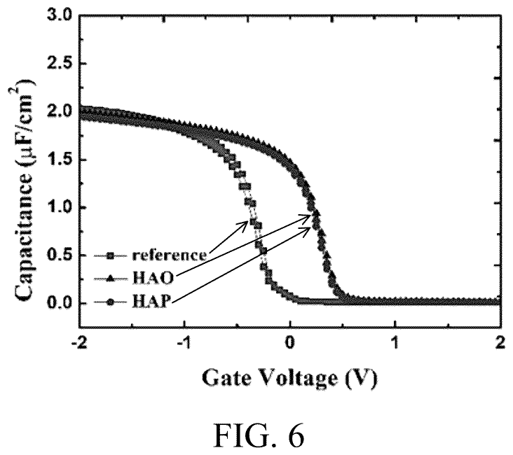

FIG. 6 is a graph of capacitance-voltage (C-V) measurement results of the MOS capacitor devices of the first reference example, the second example, and the third example. The capacitance-voltage measurement was performed at a frequency of 100 kHz. From the C-V curves in FIG. 6, it can be seen that the capacitance equivalent thickness (CET) of these three devices is almost the same, being approximately 1.4 nm. In addition, the hysteresis of the C-V curve reflects the density of charges or traps in the dielectric layer. The hysteresis window of the device of the first reference example is the largest (37.3 mV), while the hysteresis windows of the HAO and I-AP devices are significantly reduced to 15.3 mV and 14.2 mV, respectively. This result indicates that the use of hydrogen plasma treatment in the present invention can effectively reduce charge traps in the HfO₂ ultra-thin insulating layer.

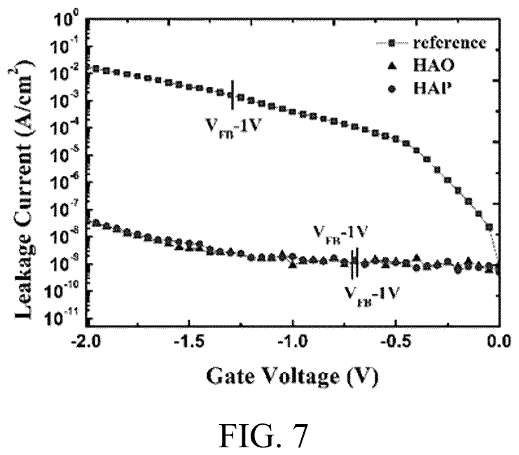

FIG. 7, is a graph of leakage current density-voltage measurement results of the MOS capacitor devices of the first reference example, the second example, and the third example. The leakage current densities of the three elements can be obtained. The leakage current density (J_{g}) is defined as the current density value measured at the flatband voltage (V_{FB}) minus 1 volt (V_{FB}-1V). As observed in FIG. 7, the leakage current density (J_{g}) of the device of the first reference example is as high as 1.62×10⁻³ A/cm². In contrast, the J_{g} of the HAO and HAP devices treated with hydrogen plasma decreases significantly to 1.25×10⁻⁹ A/cm² and 1.17×10⁻⁹ A/cm², respectively. This reduction in leakage current exceeds six orders of magnitude, fully demonstrating the excellent effectiveness of the method of the present invention in suppressing leakage current density. The results fully support the conclusion that the leakage current density of the ultra-thin insulating layer manufactured according to the method of the present invention is equal to or less than 2×10⁻⁵ A/cm². The relevant electrical parameters of the three devices obtained from the results of FIG. 6 and FIG. 7 are summarized in Table 1 below. Table 1 also lists the interfacial state density (D_{H}) of the three devices.

TABLE 1

| | device first | second | third |
|---|---|---|---|
| electrical parameter | reference example | example | example |
| total thickness of | 5.33 | 5.30 | 5.28 |
| insulating layer (nm) | | | |
| CET(nm) | 1.40 | 1.43 | 1.47 |
| J_{g}(A/cm²) | 1.62 × 10⁻³ | 1.25 × 10⁻⁹ | 1.17 × 10⁻⁹ |
| Dᵢₜ (#/cm²) | 9.27 × 10¹¹ | 8.05 × 10¹¹ | 5.25 × 10¹¹ |
| hysteresis (mV) | 37.3 | 15.3 | 14.2 |

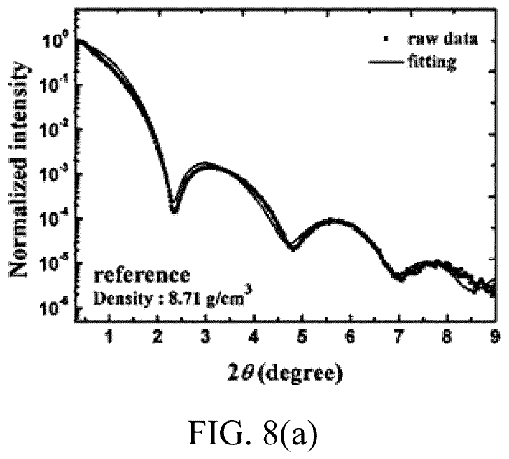

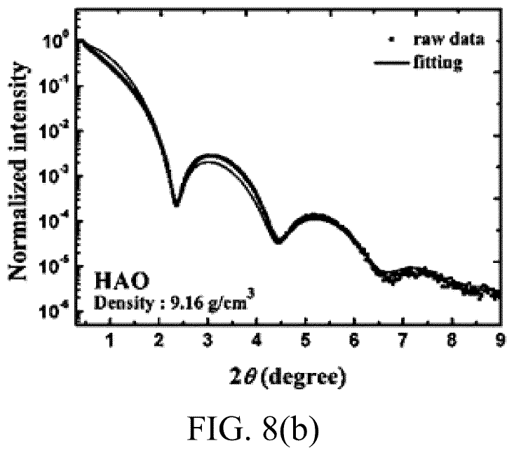

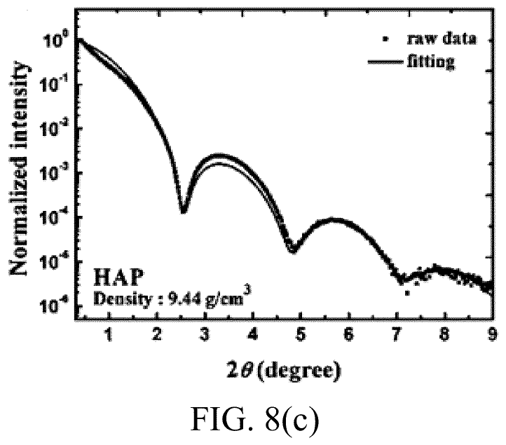

FIG. 8(a), FIG. 8(b), and FIG. 8(c) are X-ray reflectivity (XRR) patterns and their fitting curves for the HfO₂ ultra-thin insulating layers of the first reference example, the second example, and the third example, respectively. To explore the physical mechanism underlying the significant reduction in leakage current, XRR measurement techniques were utilized to analyze the density of the ultra-thin insulating layer. As shown in FIG. 8(a), FIG. 8(b), and FIG. 8(c), the film density can be obtained by fitting the XRR curves. The density of the HfO₂ ultra-thin insulating layer of the first reference example is 8.71 g/cm³. The HAO treatment leads to in increase in the density of the HfO₂ ultra-thin insulating layer to 9.16 g/cm³. For the sample treated with the HAP process, the density of the HfO₂ ultra-thin insulating layer reaches a maximum value of 9.44 g/cm³. The significant increase in the density of the ultra-thin insulating layer indicates a more compact atomic arrangement and reduced defects and voids, thereby effectively suppressing leakage current paths. This result is highly correlated with the leakage current measurement data, i.e., the HAP device exhibiting the highest film density corresponds to the lowest leakage current.

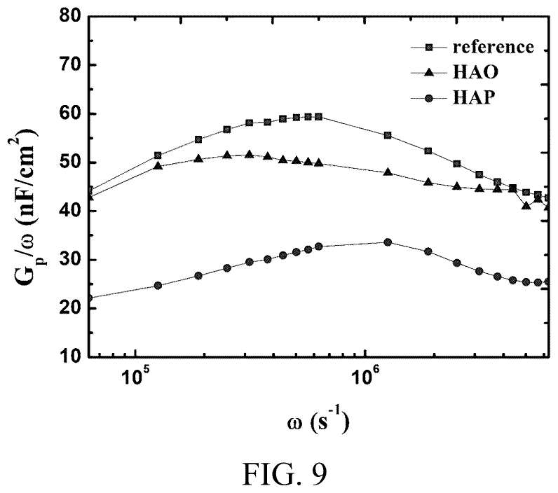

In addition, the interface quality between the high-k dielectric layer and the silicon substrate can be evaluated by the interface trap density (Dᵢₜ), which can be further determined using the conductance method. FIG. 9 is a graph showing the relationship between normalized parallel conductance (Gₚ/ω) and angular frequency ω measured by the conductance method for the devices of the second example, the third example, and the first reference example. Herein, Gₚ is the equivalent parallel conductance, and its peak value (Gₚ/ω)ₘₐₓ is proportional to Dᵢₜ. As observed in FIG. 9, the HAP device exhibits the lowest (Gₚ/ω)ₘₐₓ value, corresponding to the lowest Dᵢₜ value of 5.25×10¹¹ #/cm² (see Table 1). This superior interface quality can be attributed to the effective removal of organic ligands of the precursor chemically adsorbed on the surface by the hydrogen plasma in the HAP process. This process reduces steric hindrance, thereby improving the quality of chemical bonding at the interface.

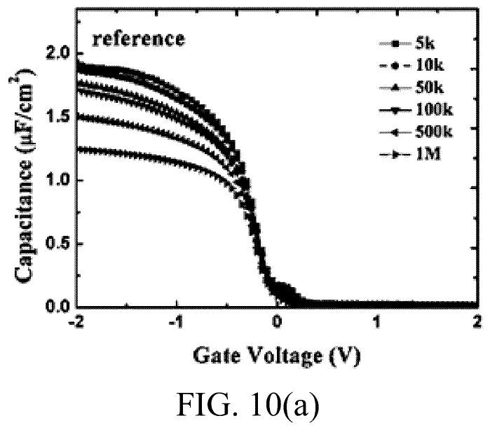

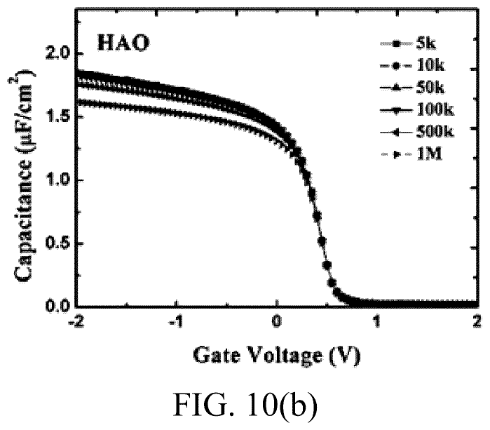

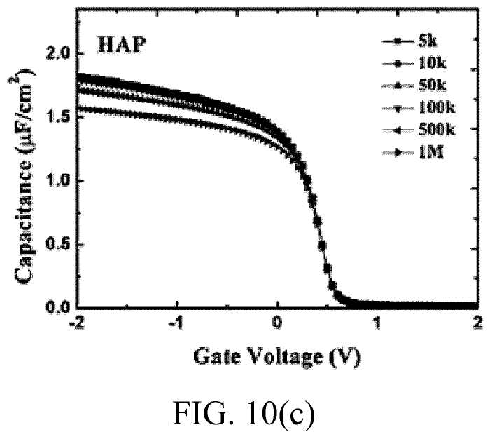

FIG. 10(a), FIG. 10(b), and FIG. 10(c) are C-V curves of the devices of the second example, the third example, and the first reference example, respectively, measured at different frequencies to evaluate their frequency dispersion characteristics. FIG. 10(a) shows that the capacitance value of the device of the first reference example in the accumulation region decreases significantly with increasing frequency, exhibiting a capacitance loss (frequency dispersion) of 54.9% from 5 kHz to 1 MHz. This severe frequency dispersion mainly originates from the parasitic series resistance effect caused by excessive leakage current. In contrast, as shown in FIG. 10(b) and FIG. 10(c), the C-V curves of the HAO and HAP devices show a reduced capacitance decay with increasing frequency, and their frequency dispersions in the range of 5 kHz to 1 MHz are only 14.2% and 15.8%, respectively. This result further demonstrates that the hydrogen plasma treatment, by significantly suppressing leakage current, effectively mitigates the effect of parasitic resistance. Furthermore, by reducing the density of border traps, more stable high-frequency operating characteristics are obtained.

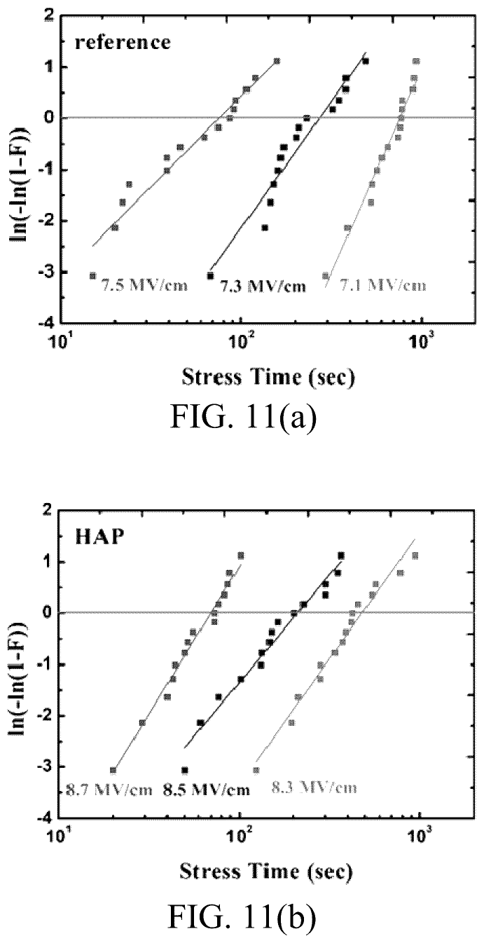

To evaluate the impact of the ultra-thin insulating layer manufactured by the method of the present invention on the long-term reliability of MOS capacitor devices, the present invention performed TDDB measurements on the MOS capacitor device of the first reference example and the HAP MOS capacitor device (third example), which exhibited the best electrical characteristics. This test measures the time required for permanent breakdown to occur under a constant high electric field stress applied to the MOS capacitor devices. FIG. 11(a) and FIG. 11(b) are Weibull plots obtained from TDDB tests performed under different electric fields for the devices of the first reference example and the HAP device, respectively. FIG. 11(a) shows the Weibull plots of the device of the first reference example under Electric fields of 7.1, 7.3, and 7.5 MV/cm, while FIG. 11(b) plots the data of the HAP device under electric fields of 8.3, 8.5, and 8.7 MV/cm. Both figures show a good Weibull distribution between cumulative breakdown probability and applied stress time. As observed in FIG. 11(a) and FIG. 11(b), the breakdown time distribution of both devices is highly concentrated, indicating good uniformity in film quality.

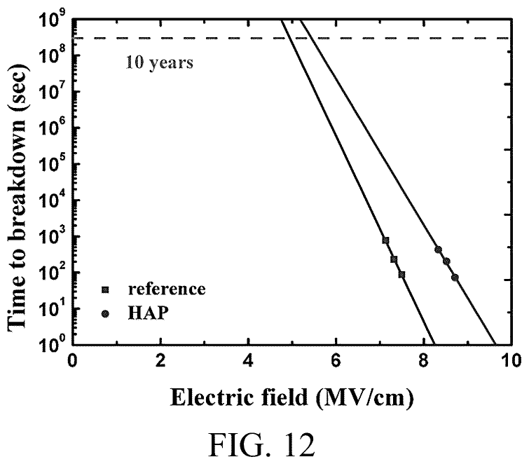

FIG. 12 is a graph showing the relationship between characteristic breakdown time and applied electric field stress for the MOS capacitor devices of the first reference example (denoted as “reference”) and the third example (denoted as “HAP”). By plotting the characteristic breakdown time (t_{63.2%}), which corresponds to a cumulative breakdown probability of 63.2% under different electric fields, and extrapolating the data, the maximum electric field that the MOS capacitor device can withstand for 10 years of continuous operation at normal operating voltage can be estimated. As shown in FIG. 12, the maximum electric field that the device of the first reference example can withstand for 10 years of operation is 4.9 MV/cm. In contrast, the I-AP device exhibits an increased maximum withstand electric field of 5.5 MV/cm. This result clearly indicates that the high-k dielectric layer manufactured by the HAP process, due to superior film quality and lower defect density, can effectively retard the generation of defects induced by the electric field, thereby significantly improving the long-term operational reliability of the MOS capacitor device.

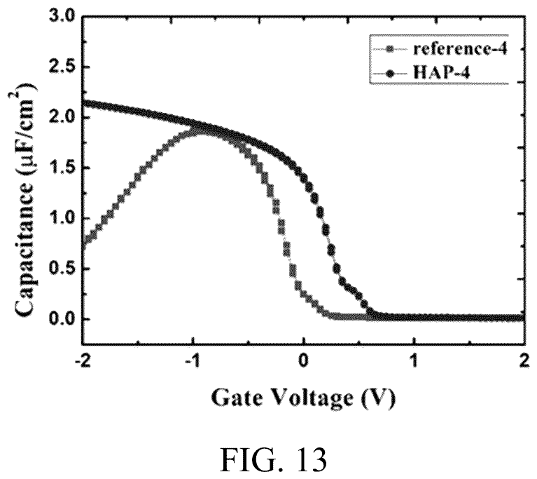

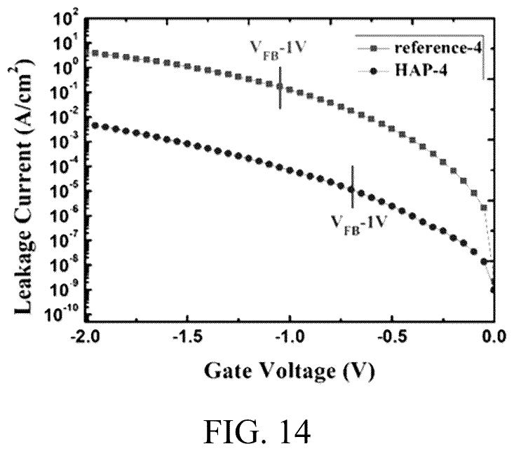

To evaluate the applicability of the method of the present invention in more advanced semiconductor technology nodes, MOS capacitor devices were fabricated with the total thickness of the ultra-thin insulating layer reduced to about 4 nanometers. These devices are referred to as the second reference example (denoted as “reference-4”) and HAP(denoted as “HAP-4”) devices, respectively. FIG. 13 is a graph of capacitance-voltage (C-V) measurement results for the devices of the second reference example (reference-4) and HAP (HAP-4), and FIG. 14 is a graph of leakage current density-voltage measurement results for the devices of the second reference example (reference-4) and HAP (HAP-4). As shown in FIG. 13 and FIG. 14, as the thickness of the ultra-thin insulating layer decreases, the leakage current inevitably increases. The device of the second reference example (reference-4) exhibits significant distortion and capacitance degradation in the C-V curve under negative voltage, which is attributed to a sharp increase in leakage current. However, the HAP-4 device maintains superior and distortion-free C-V characteristics even with the reduced insulating layer thickness. Furthermore, its leakage current density (1.14×10⁻⁵ A/cm²) is still more than four orders of magnitude lower than the leakage current density (2.47×10⁻¹ A/cm²) of the device of the second reference example (reference-4). This leakage current value satisfies the criterion that the leakage current density of the ultra-thin insulating layer manufactured according to the method of the present invention is equal to or less than 2×10⁻⁵ A/cm². (As mentioned earlier, the leakage current density (J_{g}) is defined as the current density value measured at V_{FB}-1V). This result strongly demonstrates that the method of the present invention can effectively improve the quality of the dielectric layer and exhibit excellent leakage current suppression capability, even under conditions where the thickness of the insulating layer is significantly scaled down.

In a fourth example, a fifth example, and a third reference example (reference) of the present invention, hafnium oxide (HfO₂) high-k dielectric layers were fabricated to form metal-insulator-metal (MIM) capacitor devices. The structure of the MIM capacitor device, from bottom to top, comprises a Si substrate, a TiN adhesion layer, a ruthenium (Ru) bottom electrode, the hafnium oxide (HfO₂) high-k dielectric layer, and a tungsten (W) top electrode. The precursor used in the fourth example, the fifth example, and the third reference example of the present invention was tetrakis(dimethylamino) hafnium (TDMAHf), and the reactant was water vapor (H₂O). The deposition temperature of the HfO₂ ultra-thin insulating layer was set to 300° C.

The fourth example of the present invention utilizes the HAO process described in the present invention, wherein the energy provided by the hydrogen plasma is transferred to the newly formed atomic layer of the HfO₂ film. This process facilitates the migration and rearrangement of adatoms to achieve an atomic-level annealing effect, thereby improving the density and structure of the HfO₂ film. The fourth example of the present invention employed a hydrogen plasma treatment with a plasma power equal to 50 W and a plasma duration of 7.5 seconds.

The fifth example of the present invention utilizes the HAP process described in the present invention. The key mechanism of this process is that prior to introducing the H₂O reactant, a hydrogen plasma treatment is used to effectively remove the organic ligands on the TDMAHf molecules chemically adsorbed on the surface. Removing these ligands can significantly reduce steric hindrance, allowing subsequent H₂O molecules to undergo a more complete chemical reaction with Hf atoms, thereby forming a HfO₂ film with reduced defect density and enhanced quality.

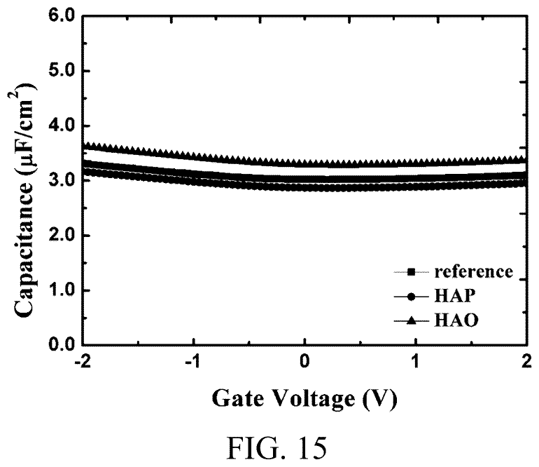

FIG. 15 is a graph of capacitance-voltage (C-V) measurement results of the MIM capacitor devices of the third reference example (denoted as “reference”), the fourth example (denoted as “HAO”), and the fifth example (denoted as “HAP”), wherein the thickness of the HfO₂ film is about 5 nm. The capacitance-voltage measurement was performed at a frequency of 100 kHz. As observed in FIG. 15, i the capacitance equivalent thickness (CET) of the three devices is substantially the same, being approximately 1 nm.

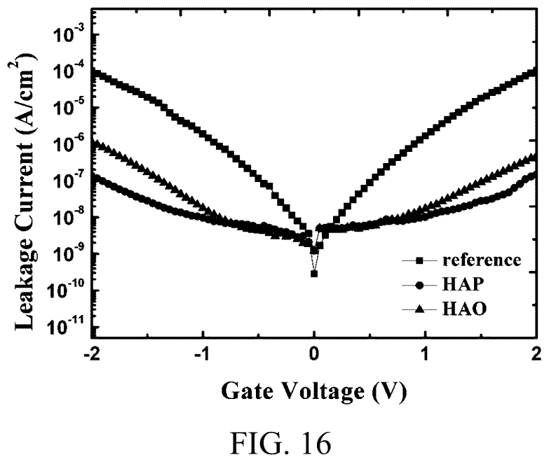

FIG. 16 is a graph of leakage current density-voltage measurement results of the MIM capacitor devices of the third reference example (reference), the fourth example (HAO), and the fifth example (HAP), from which the leakage current densities of the three devices can be obtained. As observed in FIG. 16, the leakage current density (J_{g}) of the device of the third reference example at an applied voltage of −1V is 1.88×10⁻⁶ A/cm². In contrast, the J_{g} (at an applied voltage of −1V) of the HAO and HAP devices treated with hydrogen plasma drops sharply to 1.79×10⁻⁸ A/cm² and 9.72×10⁻⁹ A/cm², respectively. This reduction in leakage current exceeds two orders of magnitude, fully demonstrating the excellent effectiveness of the method of the present invention in suppressing leakage current density. The results fully support the conclusion that the leakage current density of the surface passivation layer manufactured according to the method of the present invention is equal to or less than 1×10⁻⁶ A/cm². The relevant key electrical parameters of the three devices obtained from the results of FIG. 15 and FIG. 16 are summarized in Table 2 below.

TABLE 2

| electrical | device third | fourth | fifth |
|---|---|---|---|
| parameter | reference example | example | example |
| CET(nm) | 1.04 | 0.95 | 1.09 |
| J_{g}(A/cm²) | 1.88 × 10⁻⁶ | 1.79 × 10⁻⁸ | 9.72 × 10⁻⁹ |
| (@−1 V) | | | |

Through the above detailed description of the present invention, it can be clearly understood that the method of the present invention strategically introduces an in-situ hydrogen plasma treatment into the atomic layer deposition cycle. By performing hydrogen plasma treatment at different timings (specifically, after precursor adsorption on the surface and before reactant introduction into the chamber, or after reactant introduction into the chamber), the beneficial effects of removing precursor ligands to reduce steric hindrance and achieving atomic-level annealing to improve film density are realized, respectively. Consequently, the present invention substantially improves the material quality of the ultra-thin insulating layer, significantly reducing the leakage current density and enhancing film density, interface quality, reliability, and high-frequency stability. The method of the present invention not only provides an effective solution for the manufacture of high-performance high-k dielectric layers required for next-generation semiconductor devices, but the ultra-thin and low-leakage insulating layer prepared thereby can also be extended to applications in the field of advanced thermal management, demonstrating its high technical value and broad industrial application potential.

With the examples and explanations described above, the characteristics and spirits of the invention have been well described. Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of manufacturing an ultra-thin insulating layer on a material layer of a material structure placed in a reaction chamber, said method being performed by a plurality of atomic layer deposition (ALD) cycles, wherein each of the plurality of ALD cycles comprises the steps of:
(a) introducing at least one first gas pulse into the reaction chamber, the at least one first gas pulse comprising a precursor to cause the precursor to be adsorbed on the material layer, wherein the precursor comprises a metal element or a metalloid element;
(b) introducing a purge gas into the reaction chamber;
(c) introducing a second gas pulse into the reaction chamber to react with the precursor adsorbed on the material layer to form an atomic layer of the ultra-thin insulating layer, wherein the second gas pulse comprises a reactant;
(d) introducing the purge gas into the reaction chamber; and
(e) alternatively, between step (b) and step (c) or after step (d), introducing a hydrogen plasma into the reaction chamber and subsequently introducing the purge gas into the reaction chamber.

2. The method of claim 1, wherein in step (e), a plasma power of the hydrogen plasma ranges from 10 W to 600 W, and a duration of introducing the hydrogen plasma step ranges from 3 seconds to 60 seconds.

3. The method of claim 2, further comprising the step of:
performing a post-annealing treatment on the ultra-thin insulating layer, wherein a temperature of the post-annealing treatment ranges from 300° C. to 1000° C., and a duration of the post-annealing treatment ranges from 3 seconds to 10 minutes.

4. The method of claim 1, wherein the ultra-thin insulating layer is formed of a metal oxide or a metalloid oxide.

5. The method of claim 4, wherein the metal oxide or the metalloid oxide is selected from the group consisting of HfO₂, ZrO₂, HfₓZr₁₋ₓO₂ (0≤x≤1), Ta₂O₃, Al₂O₃, Gd₂O₃, La₂O₃, SiO₂, TiO₂, and Y₂O₃, and combinations thereof.

6. The method of claim 1, wherein the ultra-thin insulating layer comprises a metal nitride or a metalloid nitride.

7. The method of claim 6, wherein the metal nitride or the metalloid nitride is selected from the group consisting of AlNₓ, SiNₓ, GeNₓ, and BNₓ, and combinations thereof, wherein 0.5≤x≤1.5.

8. The method of claim 1, wherein the ultra-thin insulating layer serves as a dielectric layer, and a leakage current density of the ultra-thin insulating layer is equal to or less than 2×10⁻⁵ A/cm².

9. The method of claim 1, wherein the ultra-thin insulating layer serves as a surface passivation layer, and a leakage current density of the ultra-thin insulating layer is equal to or less than 1×10⁻⁶ A/cm².

10. The method of claim 1, wherein the material structure is selected from the group consisting of an integrated circuit (IC) device structure, an optoelectronic device structure, and an optical device structure; wherein the ultra-thin insulating layer serves as a surface passivation layer, and a thickness of the ultra-thin insulating layer ranges from 3 nm to 50 nm.
